(19) United States
(12) Patent Application Publication
(10) Pub. No.: US 2026/0150350 A1
(43) Pub. Date: May 28, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Ryota SUZUKI, Nisshin-shi (JP)

(21) Appl. No.: 19/385,343

(22) Filed: Nov. 11, 2025

(30) Foreign Application Priority Data
Nov. 22, 2024 (JP) 2024-204134

(51) Int. Cl. H10D 62/10; H10D 30/66; H10D 62/00; H10D 62/832

(52) U.S. Cl. CPC H10D 62/111; H10D 30/665; H10D 30/668; H10D 62/054; H10D 62/107; H10D 62/8325

(57) ABSTRACT

A semiconductor substrate in a semiconductor device has an active region, a first outer peripheral region surrounding the active region, and a second outer peripheral region surrounding the first outer peripheral region. The first outer peripheral region has an outer peripheral high breakdown-voltage structure disposed in a vicinity of an upper surface of the semiconductor substrate. The second outer peripheral region is positioned in a range from an outer periphery of the first outer peripheral region to an outer peripheral end of the semiconductor substrate. The semiconductor substrate includes a first superjunction layer disposed across the active region and the first outer peripheral region, and a second superjunction layer disposed within the second outer peripheral region and surrounding the first superjunction layer. The first superjunction layer includes first columns and second columns. The second superjunction layer includes at least one first loop portion and at least one second loop portion.

### CROSS REFERENCE TO RELATED APPLICATION

The present application claims the benefit of priority from Japanese Patent Application No. 2024-204134 filed on Nov. 22, 2024. The entire disclosure of the above application is incorporated herein by reference.

### TECHNICAL FIELD

The present disclosure relates to a semiconductor device.

### BACKGROUND

Semiconductor devices having a superjunction structure have been known. In cases where p-type columns and n-type columns constituting the superjunction structure are alternately arranged in a stripe pattern over the entire surface of an element, a pattern of the superjunction structure is simplified, miniaturization becomes easier, and a resistance of the superjunction structure can be reduced.

### SUMMARY

A semiconductor device according to an aspect of the present disclosure includes a semiconductor substrate having an upper surface and a lower surface, an upper electrode disposed above the upper surface of the semiconductor substrate, and a lower electrode disposed on the lower surface of the semiconductor substrate. The semiconductor substrate has an active region in which a device structure capable of controlling current that flows between the upper electrode and the lower electrode is disposed, a first outer peripheral region surrounding the active region, and a second outer peripheral region surrounding the first outer peripheral region. The first outer peripheral region has an outer peripheral high breakdown-voltage structure disposed in a vicinity of the upper surface of the semiconductor substrate. The second outer peripheral region is positioned in a range from an outer periphery of the first outer peripheral region to an outer peripheral end of the semiconductor substrate. The semiconductor substrate may include a first superjunction layer disposed across the active region and the first outer peripheral region, and positioned below the outer peripheral high breakdown-voltage structure, and a second superjunction layer disposed within the second outer peripheral region and surrounding the first superjunction layer. The first superjunction layer may include a plurality of first columns of a first conductivity type and a plurality of second columns of a second conductivity type. The plurality of first columns and the plurality of second columns may extend in a first direction and may be alternately arranged along a second direction orthogonal to the first direction. The second superjunction layer may include at least one first loop portion of the first conductivity type and at least one second loop portion of the second conductivity type. Each of the at least one first loop portion and the at least one second loop portion may have an annular shape and surround the first superjunction layer. The at least one first loop portion and the at least one second loop portion may be alternately arranged from a position within the second outer peripheral region close to the first outer peripheral region toward the outer peripheral end of the semiconductor substrate.

### BRIEF DESCRIPTION OF DRAWINGS

Objects, features and advantages of the present disclosure will become apparent from the following detailed description made with reference to the accompanying drawings. In the drawings:

FIG. 1 is a top view of a semiconductor substrate according to a first embodiment;

FIG. 2 is a cross-sectional view of the semiconductor device taken along line II-II of FIG. 1;

FIG. 3 is a top view of a semiconductor substrate in region RIII of FIG. 1;

FIG. 4 is a diagram illustrating a process for forming a first superjunction layer and a second superjunction layer;

FIG. 5 is a diagram illustrating the process for forming the first superjunction layer and the second superjunction layer;

FIG. 6 is a diagram illustrating the process for forming the first superjunction layer and the second superjunction layer;

FIG. 7 is a diagram illustrating the process for forming the first superjunction layer and the second superjunction layer;

FIG. 8 is a cross-sectional view of a semiconductor device according to a second embodiment;

FIG. 9 is a cross-sectional view of the semiconductor device taken along line IX-IX of FIG. 8; and

FIG. 10 is a cross-sectional view of a semiconductor device according to a third embodiment.

### DETAILED DESCRIPTION

In semiconductor devices having a superjunction structure, there are cases where longitudinal end portions of p-type columns and n-type columns reach an outer peripheral end of a substrate. However, in cases where the outer peripheral end of the semiconductor substrate is at the same potential as a lower electrode, there is a possibility that a leakage path extending from an upper electrode to the lower electrode via the p-type columns or the n-type columns and the outer peripheral end of the substrate is formed.

A semiconductor device according to a first aspect of the present disclosure includes a semiconductor substrate, an upper electrode disposed above the semiconductor substrate, and a lower electrode disposed on a lower surface of the semiconductor substrate. The semiconductor substrate has an active region in which a device structure capable of controlling current that flows between the upper electrode and the lower electrode is disposed, a first outer peripheral region that surrounds the active region, and in which an outer peripheral high breakdown-voltage structure is formed in a vicinity of an upper surface of the semiconductor substrate, and a second outer peripheral region that surrounds the first outer peripheral region and is positioned in a range from an outer periphery of the first outer peripheral region to an outer peripheral end of the semiconductor substrate. The semiconductor substrate includes a first superjunction layer disposed across the active region and the first outer peripheral region and positioned below the outer peripheral high breakdown-voltage structure, and a second superjunction layer disposed within the second outer peripheral region and surrounding the first superjunction layer. The first superjunction layer includes a plurality of first columns of a first conductivity type and a plurality of second columns of a second conductivity type. The plurality of first columns and the plurality of second columns extend in a first direction and are alternately arranged along a second direction orthogonal to the first direction. The second superjunction layer includes at least one first loop portion of a first conductivity type and at least one second loop portion of a second conductivity type. Each of the at least one first loop portion and the at least one second loop portion has an annular shape and surrounds the first superjunction layer. The at least one first loop portion and the at least one second loop portion are alternately arranged from a position within the second outer peripheral region close to the first outer peripheral region toward the outer peripheral end of the semiconductor substrate.

In the above structure, the first superjunction layer is surrounded by the annular first loop portion of the first conductivity type and the annular second loop portion of the second conductivity type. As a result, the longitudinal end portions of the first columns and second columns included in the first superjunction layer can be isolated from the outer peripheral end of the semiconductor substrate. This makes it possible to prevent the formation of a leakage path via the plurality of first columns or the plurality of second columns between the upper electrode and the outer peripheral end of the semiconductor substrate. In addition, in the above structure, by providing the outer peripheral high breakdown-voltage structure, it is possible to control the extension amount of the depletion layer the lateral direction parallel to the upper surface of the semiconductor substrate. It thus becomes possible to obtain favorable breakdown voltage characteristics even at the outer peripheral portion of the semiconductor substrate.

### First Embodiment

### Structure of Semiconductor Device 1

Hereinafter, with reference to the drawings, semiconductor devices to which a technology disclosed in the present specification is applied will be described. In the drawings, only some of common components may be denoted by reference numerals for the purpose of clarity of illustration. In respective embodiments, common components are denoted by common reference numerals, and descriptions thereof will be omitted.

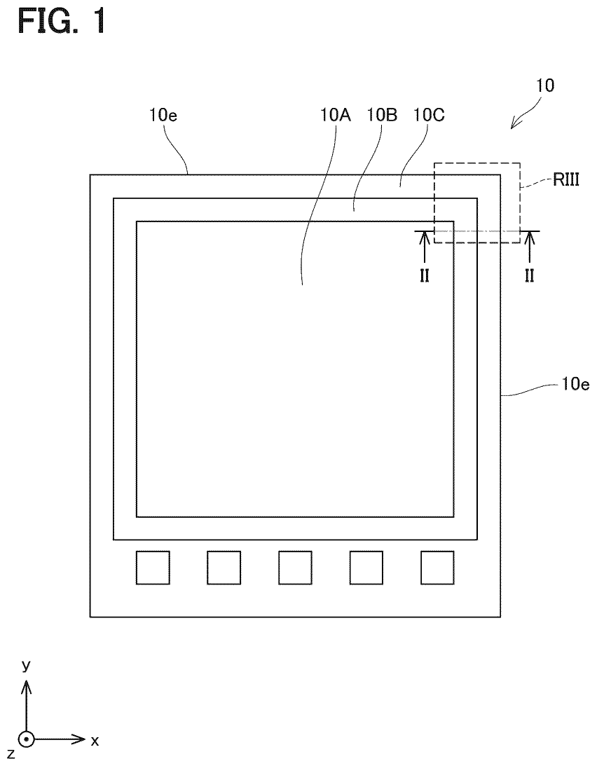

As shown in FIGS. 1 to 3, a semiconductor device 1 is a power device called a metal insulator semiconductor field effect transistor (MISFET). The material of a semiconductor substrate 10 is not particularly limited, and may be, for example, silicon or a wide bandgap semiconductor. The type of wide bandgap semiconductor is not particularly limited. Examples of the wide bandgap semiconductor include silicon carbide (SiC), gallium nitride (GaN), and gallium oxide (Ga₂O₃).

The semiconductor device 1 includes the semiconductor substrate 10. FIG. 1 shows a top view of the semiconductor substrate 10. The semiconductor substrate 10 has an active region 10A, a first outer peripheral region 10B, and a second outer peripheral region 10C when viewed from a direction (+z direction) perpendicular to a surface of the semiconductor substrate 10. The active region 10A is a region in which a device structure capable of controlling current that flows between an upper electrode 24 and a lower electrode 22 is formed. The first outer peripheral region 10B surrounds the active region 10A. The first outer peripheral region 10B is a region in which a peripheral high breakdown-voltage structure, which will be described later, is disposed. The second outer peripheral region 10C surrounds the first outer peripheral region 10B. The second outer peripheral region 10C is a region extending from an outer periphery of the first outer peripheral region 10B to an outer peripheral end 10e of the semiconductor substrate 10.

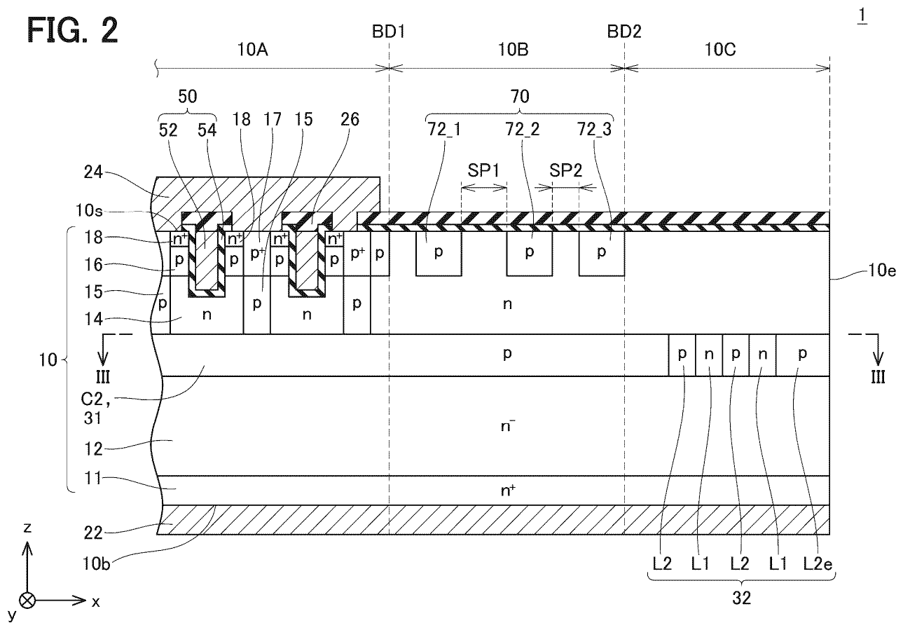

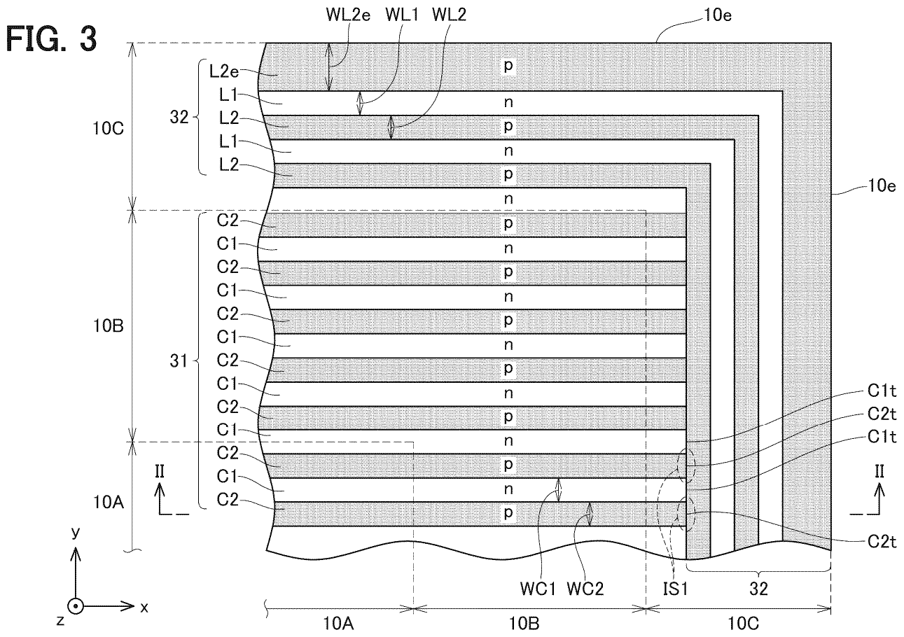

FIG. 2 shows a cross-sectional view taken along line II-II of FIG. 1. FIG. 2 is also a cross-sectional view taken along line II-II of FIG. 3. That is, FIG. 2 is a cross-sectional view taken along a second column C2 of a first superjunction (SJ) layer 31. FIG. 3 shows a top view of region RIII in FIG. 1. FIG. 3 is also a cross-sectional view taken along line III-III of FIG. 2. That is, in FIG. 3, the first SJ layer 31 and a second SJ layer 32 are exposed. In FIG. 3, for clarity, p-type regions are shown with gray shading.

As shown in FIG. 2, the semiconductor device 1 includes the semiconductor substrate 10, the lower electrode 22, and the upper electrode 24. The semiconductor substrate 10 has a drain region 11, a lower drift region 12, the first SJ layer 31, the second SJ layer 32, an upper drift region 14, a deep P region 15, a body region 16, a contact region 17, and a source region 18.

In FIG. 2, a plurality of trench gates 50 are provided in the active region 10A. In the active region 10A, when the semiconductor device 1 is turned on, current flows between the lower electrode 22 and the upper electrode 24. In the first outer peripheral region 10B, an outer peripheral high breakdown-voltage structure 70 is disposed. In the second outer peripheral region 10C, the second superjunction layer 32, which will be described later, is arranged. In the present embodiment, a boundary BD1 between the active region 10A and the first outer peripheral region 10B is defined by a periphery of the body region 16. A boundary BD2 between the first outer peripheral region 10B and the second outer peripheral region 10C is defined by a periphery of the outer peripheral high breakdown-voltage structure 70.

The lower electrode 22 is disposed so as to cover a lower surface 10b of the semiconductor substrate 10. The upper electrode 24 is disposed so as to cover an upper surface 10s of the semiconductor substrate 10. The upper electrode 24 is disposed over substantially the entire area of the active region 10A.

The drain region 11 is an n-type region containing n-type impurities at high concentration. The drain region 11 is disposed at a position exposed on the lower surface 10b of the semiconductor substrate 10. The drain region 11 is in ohmic contact with the lower electrode 22. The lower drift region 12 is disposed above the drain region 11 and is an n-type region having a lower n-type impurity concentration than the drain region 11. The first SJ layer 31 and the second SJ layer 32 are disposed above the lower drift region 12. The detailed structure of the first SJ layer 31 and the second SJ layer 32 will be described later.

The upper drift region 14 is an n-type region containing n-type impurities. The upper drift region 14 is in contact with upper surfaces of the first SJ layer 31 and the second SJ layer 32. The upper drift region 14 is in contact with bottom surfaces and lower portions of side surfaces of the trench gates 50.

The deep P region 15 is a p-type region containing p-type impurities. The deep P region 15 is disposed in the active region 10A and is formed so as to penetrate through the upper drift region 14. The deep P region 15 extends along a y direction.

The body region 16 is a p-type region containing p-type impurities. The body region 16 is disposed in the active region 10A and is disposed on the upper drift region 14. The body region 16 is in contact with the side surfaces of the trench gates 50 and separates the upper drift region 14 from the source region 18.

The contact region 17 is a p-type region containing p-type impurities at a higher concentration than the body region 16. The contact region 17 is disposed in the active region 10A and is formed at a position exposed on the upper surface 10s of the semiconductor substrate 10. The contact region 17 is exposed through an opening in an interlayer insulating film 26 formed on the upper surface 10s, and is in ohmic contact with the upper electrode 24.

The source region 18 is an n-type region containing n-type impurities at a high concentration. The source region 18 is disposed in the active region 10A and is formed at a position exposed on the upper surface 10s of the semiconductor substrate 10. The source region 18 is exposed through an opening in the interlayer insulating film 26 and is in ohmic contact with the upper electrode 24. The source region 18 is in contact with upper portions of the side surfaces of the trench gates 50.

Each of the plurality of trench gates 50 is provided in the active region 10A. Each of the plurality of trench gates 50 extends from the upper surface 10s of the semiconductor substrate 10, penetrates through the source region 18 and the body region 16, and reaches the upper drift region 14. The plurality of trench gates 50 extend along a y direction and are repeatedly arranged at intervals along an x direction. Each of the plurality of trench gates 50 has a gate electrode 52 and a gate insulating film 54. The gate electrode 52 is insulated from the upper drift region 14, the body region 16, and the source region 18 by the gate insulating film 54, and is also insulated from the upper electrode 24 by the interlayer insulating film 26.

The outer peripheral high breakdown-voltage structure 70 is disposed in the first outer peripheral region 10B. The outer peripheral high breakdown-voltage structure 70 includes a plurality of ring portions 72_1 to 72_3. The plurality of ring portions 72_1 to 72_3 are p-type regions containing p-type impurities. When viewed from a direction (the +z direction) perpendicular to the upper surface 10s, the plurality of ring portions 72_1 to 72_3 extend in loops around the periphery of the active region 10A. That is, the plurality of ring portions 72_1 to 72_3 have a multiple annular shape that surrounds the active region 10A.

The plurality of ring portions 72_1 to 72_3 are arranged in a repeated manner from the inner peripheral side toward the outer peripheral side when viewed from the direction perpendicular to the upper surface 10s. Portions of the upper drift region 14 are disposed between adjacent ring portions. An interval between the ring portions 72_1 and 72_2 is an interval SP1. An interval between the ring portions 72_2 and 72_3 is an interval SP2. The interval SP1 is set to be larger than the interval SP2. That is, the intervals between the plurality of ring portions 72_1 to 72_3 are larger on the inner peripheral side than on the outer peripheral side.

Each of the plurality of ring portions 72_1 to 72_3 is spaced apart from p-type columns of the first SJ layer 31, and a potential of each of the plurality of ring portions 72_1 to 72_3 is floating. The plurality of ring portions 72_1 to 72_3 may be formed, for example, by introducing p-type impurities into portions of the upper drift region 14 using an ion implantation technology.

### Structure of First SJ Layer 31 and Second SJ Layer 32

The first SJ layer 31 is disposed so as to extend across both the active region 10A and the first outer peripheral region 10B. Furthermore, the first SJ layer 31 is disposed on the lower side (in the-z direction) relative to the outer peripheral high breakdown-voltage structure 70. As shown in FIG. 3, the first SJ layer 31 includes first columns C1 and second columns C2. The first columns C1 are n-type regions extending in a first direction. The second columns C2 are p-type regions extending in the first direction. The first columns C1 and the second columns C2 are alternately arranged along a second direction orthogonal to the first direction, thereby forming a stripe structure. In the present embodiment, the first direction is set to be the x direction, and the second direction is set to be the y direction. Since the first SJ layer 31 has the stripe structure, the first SJ layer 31 can be more easily and uniformly depleted. As a result, the impurity concentration of the first SJ layer 31 can be increased, making it possible to reduce the resistance of the first SJ layer 31.

The second columns C2 are electrically connected to the upper electrode 24 via the deep P region 15 and the contact region 17. As a result, the potential of the second columns C2 is fixed to a source potential.

The second SJ layer 32 is disposed in the second outer peripheral region 10C and surrounds the first SJ layer 31. The second SJ layer 32 includes at least one first loop portion L1 and at least one second loop portion L2. In the present embodiment, the second SJ layer 32 includes two first loop portions L1 and three second loop portions L2, for example. The first loop portions L1 are annular n-type regions that surround the first SJ layer 31. The second loop portions L2 are annular p-type regions that surround the first SJ layer 31. The first loop portions L1 and the second loop portions L2 are alternately arranged in the second outer peripheral region 10C from a position within the second outer peripheral region 10C close to the first outer peripheral region 10B toward the outer peripheral end 10e of the semiconductor substrate 10.

Among the plurality of second loop portions L2, the outermost loop portion is referred to as an outermost second loop portion L2e. The outermost second loop portion L2e includes the outer peripheral end 10e of the semiconductor substrate 10. One of the first loop portions L1 is in contact with the entire inner periphery of the outermost second loop portion L2e. That is, the outermost second loop portion L2e is isolated by the first loop portion L1. The outermost second loop portion L2e has a width WL2e in the short direction. Each of the other second loop portions L2 has a width WL2 in the short direction. The width WL2e is greater than the width WL2.

Each of the plurality of first columns C1 has a width WC1 in the short direction. Each of the plurality of first loop portions L1 has a width WL1 in the short direction. The width WC1 and the width WL1 are all equal to each other.

Each of the plurality of second columns C2 has a second column end portion C2t, which is an end portion in the x direction. The second column end portion C2t is positioned within the second outer peripheral region 10C. The second column end portion C2t is in contact with the second loop portion L2, which is positioned at the innermost periphery. That is, a plurality of intersection points IS1 are formed by the plurality of second columns C2 and the second loop portion L2 at the innermost periphery. These plurality of intersection points IS1 are positioned within the second outer peripheral region 10C.

Similarly, each of the plurality of first columns C1 has a first column end portion C1t, which is an end portion in the x direction. The first column end portion C1t is positioned within the second outer peripheral region 10C. The first column end portion C1t is in contact with the second loop portion L2 positioned at the innermost periphery, but is not in contact with the first loop portion L1 positioned at the innermost periphery. That is, the plurality of first columns C1 do not have intersection points with the first loop portions L1.

### Operation of Semiconductor Device 1

When a voltage equal to or higher than a gate threshold voltage is applied to the gate electrode 52 in a state where a voltage is applied between the drain and the source such that a potential of the lower electrode 22 is higher than a potential of the upper electrode 24, a channel is formed at a portion of the body region 16 adjacent to the gate insulating film 54. Electrons supplied from the source region 18 flow into the upper drift region 14 via the channel. The electrons that have flowed into the upper drift region 14 flow to the drain region 11 via the first columns C1 of the first SJ layer 31 and the lower drift region 12. As a result, conduction is established between the lower electrode 22 and the upper electrode 24, and the semiconductor device 1 is turned on.

When a voltage lower than the gate threshold voltage is applied to the gate electrode 52, the channel disappears and the semiconductor device 1 is turned off. When the semiconductor device 1 is turned off, the first SJ layer 31 and the second SJ layer 32 become depleted, thereby alleviating electric field concentration.

### Manufacturing Method of First SJ Layer 31 and Second SJ Layer 32

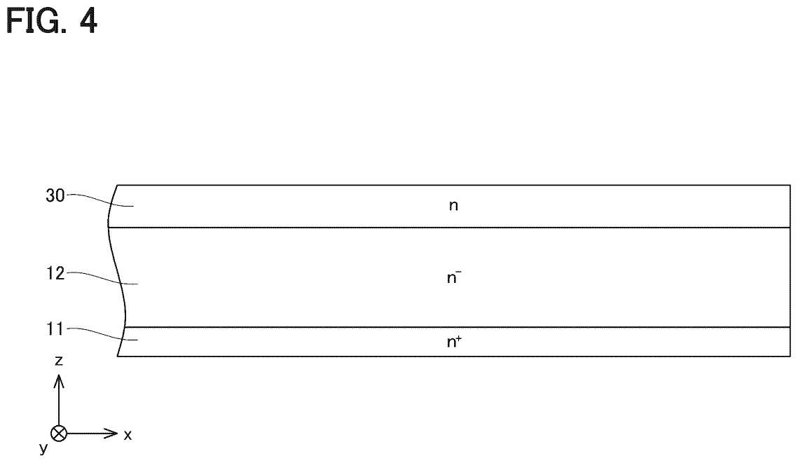

Next, with reference to FIGS. 4 to 7, a process for forming the first SJ layer 31 and the second SJ layer 32 in a manufacturing method of the semiconductor device 1 will be described. FIGS. 4 to 7 are cross-sectional views of the same region as in FIG. 2. Other processes for manufacturing the semiconductor device 1 may utilize known manufacturing technologies.

First, the drain region 11, which is an n⁺-type silicon carbide substrate, is prepared. Next, using epitaxial growth techniques, the lower drift region 12 and the epitaxial layer 30 of silicon carbide are grown from a surface of the drain region 11. As a result, the structure shown in FIG. 4 is completed. The concentration of n-type impurities is lower in the lower drift region 12 than in the epitaxial layer 30. Such a distribution of n-type impurity concentration may be adjusted during the epitaxial growth of the lower drift region 12 and the epitaxial layer 30, may be adjusted using ion implantation technology after the epitaxial growth, or may be adjusted by a combination of these methods.

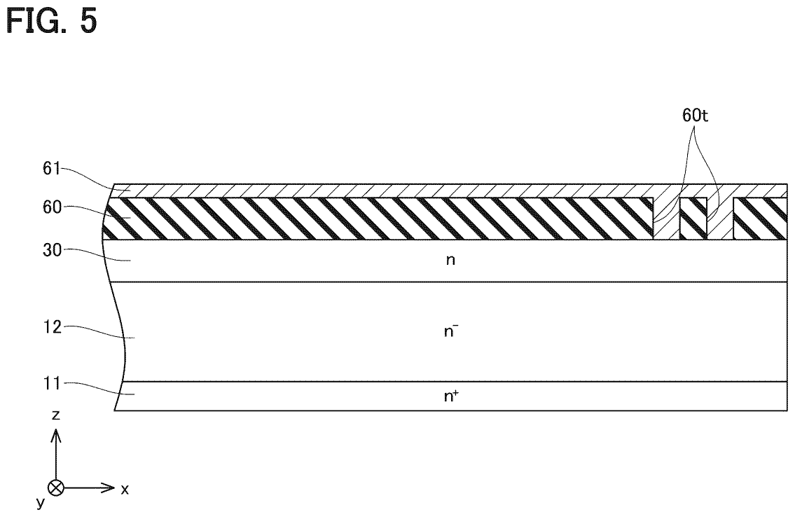

Next, a sacrificial layer 60 is formed on the epitaxial layer 30. The sacrificial layer 60 may be any film that provides sufficient etching selectivity with respect to a high shielding film, which will be described later, and the epitaxial layer 30. For example, SiO₂ can be used as the sacrificial layer 60. Next, using known photolithography and dry etching techniques, grooves 60t are formed in the sacrificial layer 60. The grooves 60t are formed at regions corresponding to the first columns C1 and the first loop portions L1. Then, a high shielding film 61 is formed over the entire surface of the epitaxial layer 30 and the sacrificial layer 60. The high shielding film 61 may be any film that has a higher ability to block implanted ions compared to a resist film or hard mask film (for example, SiO₂, SiN), and various materials can be used as the high shielding film 61. As a result, the structure shown in FIG. 5 is completed.

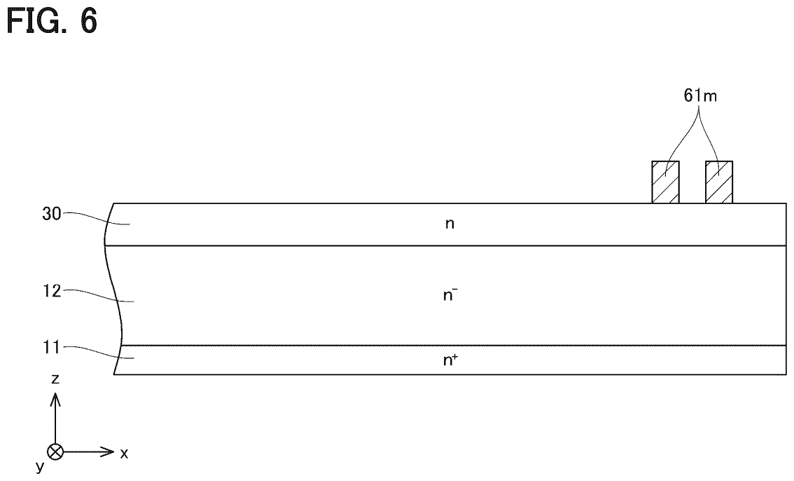

The high shielding film 61 formed on the upper surface of the sacrificial layer 60 is removed. This step may be performed, for example, by chemical mechanical polishing (CMP). As a result, the high shielding film 61 can be selectively left only within the grooves 60t. Next, the sacrificial layer 60 is removed. In this step, for example, isotropic etching such as wet etching can be used. As a result, as shown in FIG. 6, a mask 61m formed of the high shielding film 61 is completed.

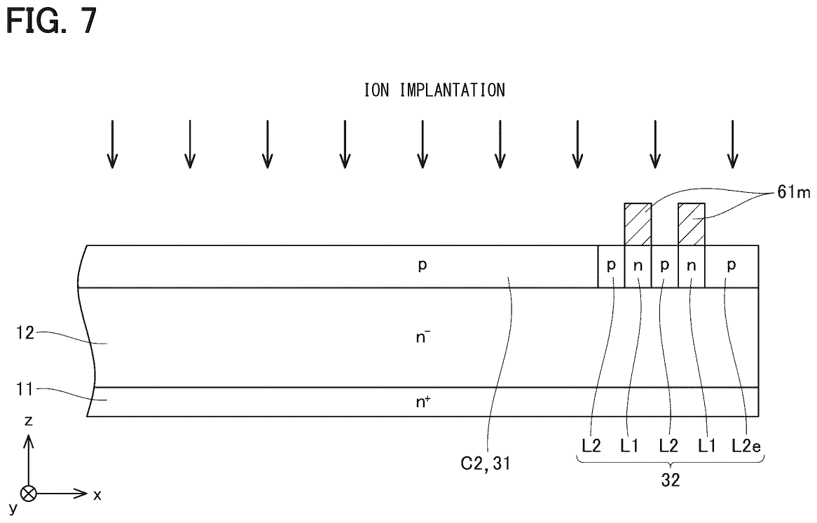

Next, as shown in FIG. 7, an ion implantation process is carried out. Specifically, p-type impurity ions are implanted in multiple stages throughout the depth of the epitaxial layer 30 through the mask 61m. Accordingly, as shown in FIG. 7, it is possible to form the second columns C2, the second loop portions L2, and the outermost second loop portion L2e, which are p-type regions.

The effects of this manufacturing method will be described. When forming a superjunction structure using deep ion implantation, a thickness of an ion implantation mask increases. In this case, if a pattern is miniaturized, mask openings will have a high aspect ratio, making it difficult to form the mask. Therefore, in the technology of the present embodiment, the high shielding film 61 with high shielding property against implanted ions is used to form the mask 61m. As a result, compared to using conventional mask materials (for example, resist, SiO₂, SiN), the thickness of the mask 61m can be reduced. Because the aspect ratio of the mask can be reduced, it is possible to miniaturize the pattern.

The high shielding film 61 may sometimes be difficult to pattern by dry etching. Therefore, in the technology of the present embodiment, the grooves 60t corresponding to the mask 61m are formed in the sacrificial layer 60 by patterning the sacrificial layer 60 using dry etching. Then, by embedding the high shielding film 61 only inside the grooves 60t, the mask 61m is formed (see FIG. 5 and FIG. 6). As a result, since it is not necessary to pattern the high shielding film 61 by dry etching, it becomes possible to form the mask 61m using the high shielding film 61.

If there are regions where multiple grooves 60t intersect each other, seams (depressions) may occur in these intersection regions after embedding the high shielding film 61. Due to the seams, the shielding property against implanted ions in the intersection regions may be reduced. Therefore, in the technology of the present embodiment, the plurality of first columns C1 and the plurality of first loop portions L1 are configured so as not to have any intersection points where they contact each other (see FIG. 3). The first columns C1 and the first loop portions L1 are regions covered by the mask 61m and correspond to the regions where the high shielding film 61 is embedded. By ensuring that these regions do not have intersection points, seams are not formed. As a result, it is possible to form the mask 61m with uniform shielding property.

In the technology of the present embodiment, the width WC1 of each of the first columns C1 and the width WL1 of each of the first loop portions L1 are all equal to each other. As a result, the widths of all the grooves 60t into which the high shielding film 61 is embedded can be made equal to each other, enabling the film thickness of the completed mask 61m to be made uniform. Thus, the mask 61m having uniform shielding property can be formed.

### Advantageous Effects

In the semiconductor device 1 of the present embodiment, the first loop portions L1 of n-type having annular shapes and the second loop portions L2 of p-type having annular shapes surround the first SJ layer 31. As a result, the first column end portions C1t and the second column end portions C2t included in the first SJ layer 31 can be isolated from the outer peripheral end 10e of the semiconductor substrate 10 (see FIG. 3). Thus, it is possible to prevent a situation in which a leakage path is formed between the upper electrode 24 and the outer peripheral end 10e of the semiconductor substrate 10 via the second column end portions C2t. In addition, the semiconductor device 1 of the present embodiment includes both the first SJ layer 31 and the outer peripheral high breakdown-voltage structure 70 in the first outer peripheral region 10B. With the first SJ layer 31, it is possible to mainly control the extension amount of the depletion layer in the vertical direction (z direction). In addition, the extension amount of the depletion layer mainly in the lateral (xy plane) direction can be controlled by the outer peripheral high breakdown-voltage structure 70. Since the extension of the depletion layer can be individually optimized in each of the first SJ layer 31 and the outer peripheral high breakdown-voltage structure 70, it is possible to achieve favorable breakdown voltage characteristics in the outer peripheral region.

In the p-type ion implantation using the mask 61m formed by embedding (see FIGS. 4 to 7), there is a constraint that the widths of the regions covered by the mask (that is, the width WC1 of the first columns C1 and the width WL1 of the first loop portions L1) cannot be made large. As a result, the vicinity of the outer peripheral end 10e of the semiconductor substrate 10 cannot be covered by the mask, so the outer peripheral end 10e inevitably becomes the outermost second loop portion L2e of p-type. Therefore, in the semiconductor device 1 of the present embodiment, the first loop portion L1 is configured to be in contact with the entire inner periphery of the outermost second loop portion L2e (see FIG. 3). As a result, the outermost second loop portion L2e of p-type can be isolated by the first loop portion L1 of n-type. This makes it possible to prevent a situation in which a leakage path by a p-type layer is created between the upper electrode 24 and the outer peripheral end 10e.

The plurality of intersection points IS1 are formed by the plurality of second columns C2 and the innermost second loop portion L2 (see FIG. 3). In the regions where the intersection points IS1 are formed, a deviation in the charge balance of the superjunction structure occurs compared to the regions where the intersection points IS1 are not formed. As a result, when a high electric field is applied to the intersection points IS1, the breakdown voltage may locally decrease. Therefore, in the semiconductor device 1 of the present embodiment, the intersection points IS1 are positioned within the second outer peripheral region 10C. The second outer peripheral region 10C is positioned further toward the outer periphery than the outer peripheral high breakdown-voltage structure 70, and is a zero electric field region where almost no electric field is applied. Accordingly, it is possible to prevent a local reduction in breakdown voltage at the intersection points IS1 caused by a deviation in charge balance.

In the semiconductor device 1 of the present embodiment, the interval between the ring portions 72_1 to 72_3 is made larger on the inner peripheral side than on the outer peripheral side (see FIG. 2). As a result, compared to the case where the interval between the ring portions is uniform, the peak of the electric field distribution can be shifted further toward the inner peripheral side. Since the electric field applied to the intersection points IS1, which are positioned within the second outer peripheral region 10C, can be reduced, it becomes possible to prevent a local reduction in breakdown voltage at the intersection points IS1.

### Second Embodiment

### Structure of Semiconductor Device 201

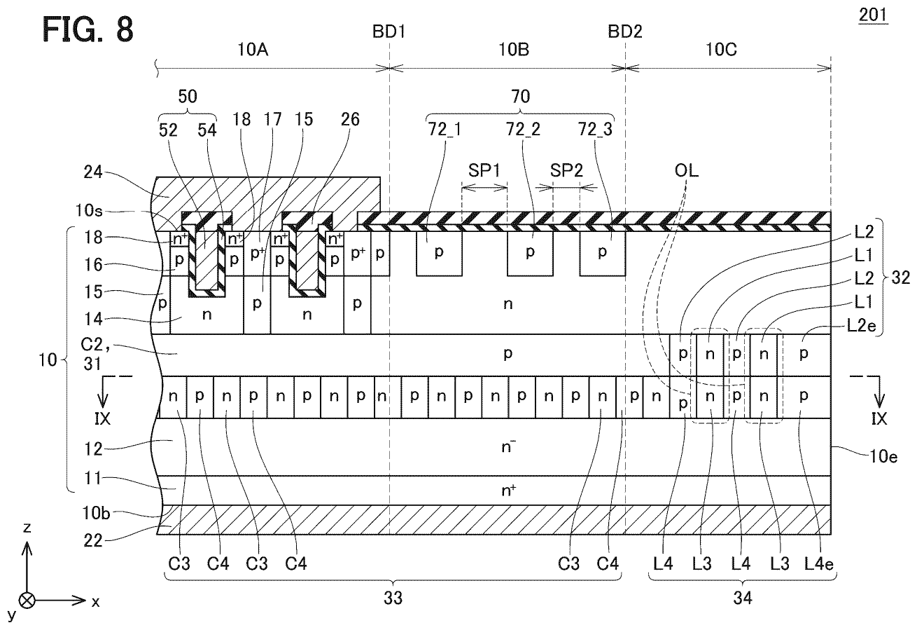

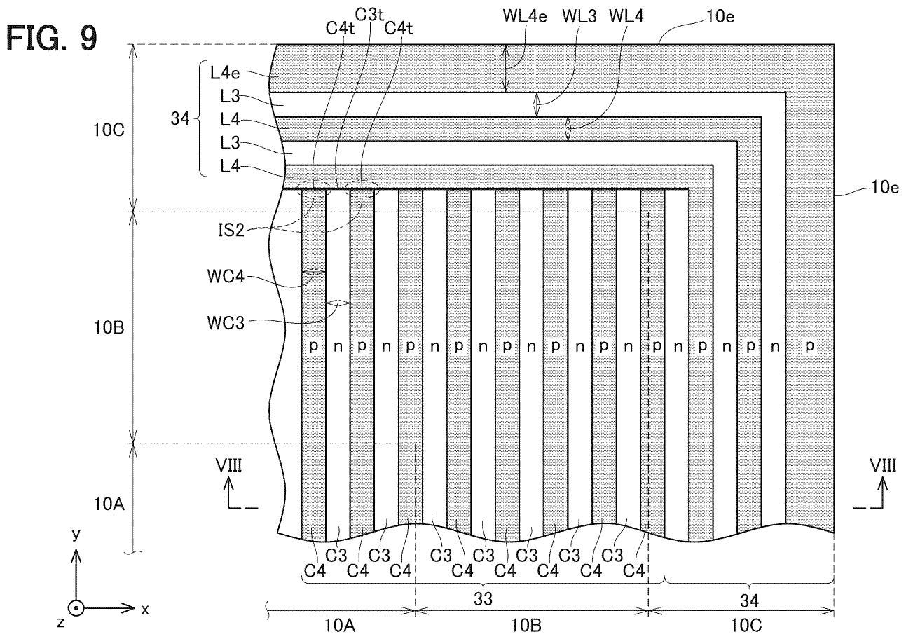

FIG. 8 shows a semiconductor device 201 according to a second embodiment. FIG. 8 is a drawing at a position similar to that of FIG. 2 in the first embodiment. FIG. 8 is also a cross-sectional view taken along line VIII-VIII of FIG. 9. Compared to the semiconductor device 1 of the first embodiment, the semiconductor device 201 of the second embodiment further includes a third SJ layer 33 and a fourth SJ layer 34. For portions common to both the first and second embodiments, the same reference numerals are used, and the description thereof is omitted. FIG. 9 shows a cross-sectional view taken along line IX-IX of FIG. 8. FIG. 9 is a drawing at a position similar to that of FIG. 3 of the first embodiment. That is, in FIG. 9, the third SJ layer 33 and the fourth SJ layer 34 are exposed. In FIG. 9, for clarity, the p-type regions are indicated by gray shading.

The third SJ layer 33 is arranged so as to extend across both the active region 10A and the first outer peripheral region 10B. The third SJ layer 33 is disposed on the lower side (−z direction side) of the first SJ layer 31 and is in contact with the first SJ layer 31. As shown in FIG. 9, the third SJ layer 33 includes a plurality of third columns C3 and a plurality of fourth columns C4. The third columns C3 are n-type regions extending in a third direction. The fourth columns C4 are p-type regions extending in the third direction. The third columns C3 and the fourth columns C4 are alternately arranged along a fourth direction orthogonal to the third direction, forming a stripe structure. In the present embodiment, the third direction is set to be the y direction, and the fourth direction is set to be the x direction. It should be noted that the third direction and the fourth direction may be set to any directions. That is, the intersection angle between the first columns C1 and the second columns C2, and the third columns C3 and the fourth columns C4, is not limited to 90 degrees, and may be any angle.

The fourth SJ layer 34 is disposed in the second outer peripheral region 10C and surrounds the third SJ layer 33. The fourth SJ layer 34 includes at least one third loop portion L3 and at least one fourth loop portion L4. In the present embodiment, the fourth SJ layer 34 includes two third loop portions L3 and three fourth loop portions L4, for example. The third loop portions L3 are annular n-type regions that surround the third SJ layer 33. The fourth loop portions L4 are annular p-type regions that surround the third SJ layer 33. The third loop portions L3 and the fourth loop portions L4 are alternately arranged from a position within the second outer peripheral region 10C close to the first outer peripheral region 10B toward the outer peripheral end 10e of the semiconductor substrate 10.

The outermost loop portion among the plurality of fourth loop portions L4 is the outermost fourth loop portion L4e. The outermost fourth loop portion L4e includes the outer peripheral end 10e of the semiconductor substrate 10. One of the third loop portions L3 is in contact with the entire inner periphery of the outermost fourth loop portion L4e. That is, the outermost fourth loop portion L4e is isolated by the third loop portion L3.

The third loop portions L3 shown in FIG. 9 have substantially the same planar shapes as the first loop portions L1 shown in FIG. 3. Additionally, the fourth loop portions L4 and the outermost fourth loop portion L4e have substantially the same planar shapes as the second loop portions L2 and the outermost second loop portion L2e. When viewed from a direction perpendicular to the upper surface 10s of the semiconductor substrate 10 (+z direction), at least a part of the first loop portions L1 and at least a part of the third loop portions L3 overlap each other to form overlapping loop portions OL (see FIG. 8). The overlapping loop portions OL surround the entire outer periphery of the first outer peripheral region 10B. Additionally, when viewed from the +z direction, the second loop portions L2 and the fourth loop portions L4 overlap, and the outermost second loop portion L2e and the outermost fourth loop portion L4e also overlap.

Each of the plurality of third columns C3 has a width WC3 in the short direction. Each of the plurality of third loop portions L3 has a width WL3 in the short direction. The width WC3 and the width WL3 are all equal to each other. Additionally, the width WC3 and the width WL3 (see FIG. 9) are set to be equal to the width WC1 and the width WL1 (see FIG. 3).

Each of the plurality of fourth columns C4 has a fourth column end portion C4t, which is an end portion in the y direction. The fourth column end portion C4t is positioned within the second outer peripheral region 10C. The fourth column end portion C4t is in contact with the fourth loop portion L4, which is positioned at the innermost periphery. That is, a plurality of intersection points IS2 are formed by the plurality of fourth columns C4 and the innermost fourth loop portion L4. These intersection points IS2 are positioned within the second outer peripheral region 10C.

Similarly, each of the plurality of third columns C3 has a third column end portion C3t, which is an end portion in the y direction. The third column end portion C3t is positioned within the second outer peripheral region 10C. The third column end portion C3t is in contact with the innermost fourth loop portion L4, but is not in contact with the innermost third loop portion L3. That is, the plurality of third columns C3 do not have intersection points with the third loop portions L3.

### Advantageous Effects

The semiconductor device 201 of the second embodiment has a structure in which two SJ layers are stacked. As a result, compared to a single-layer SJ layer, a depletion layer can be formed over a wider range in the depth direction. Since a larger potential difference can be sustained, it is possible to further increase the breakdown voltage of the semiconductor device 201.

When viewed from the +z direction, in the regions where the second loop portions L2 and the fourth loop portions L4 overlap, p-type conductive paths are formed. If these p-type conductive paths are continuously formed from the inner peripheral side to the outer peripheral side of the second outer peripheral region 10C, a leakage path through the p-type layer will be formed between the upper electrode 24 and the outer peripheral end 10e of the semiconductor substrate 10. Therefore, the semiconductor device 201 of the second embodiment has a structure in which the n-type overlapping loop portions OL surround the entire outer periphery of the first outer peripheral region 10B. As a result, the outermost second loop portion L2e of p-type and the outermost fourth loop portion L4e of p-type can be isolated by the overlapping loop portions OL of n-type. This makes it possible to prevent a situation in which a leakage path by a p-type layer is created between the upper electrode 24 and the outer peripheral end 10e.

In the semiconductor device 201 of the second embodiment, the intersection points IS2 are positioned within the second outer peripheral region 10C. Accordingly, it is possible to prevent a local reduction in breakdown voltage at the intersection points IS2 caused by a deviation in charge balance.

In the semiconductor device 201 of the second embodiment, the plurality of third columns C3 and the plurality of third loop portions L3 have a structure in which there are no intersection points where they contact each other (see FIG. 9). As a result, when forming the mask 61m by embedding the high shielding film 61, a uniform shielding property can be achieved.

In the semiconductor device 201 of the second embodiment, the width WC3 of the third columns C3 and the width WL3 of the third loop portions L3 are all equal to each other. As a result, the widths of all the grooves 60t into which the high shielding film 61 is embedded can be made equal to each other, enabling the film thickness of the completed mask 61m to be made uniform.

### Modification of Second Embodiment

The configuration in which the first SJ layer 31 and the third SJ layer 33 are stacked is not limited to the configuration of the second embodiment, and various configurations may be employed. For example, the third columns C3 and the fourth columns C4 of the third SJ layer 33 may extend in the x direction. That is, the third columns C3 and the fourth columns C4 may be parallel to the first columns C1 and the second columns C2. In this case, the width WC3 of the third columns C3 and the width WC4 of the fourth columns C4 may be equal to the width WC1 of the first columns C1 and the width WC2 of the second columns C2. Then, when viewed from the +z direction, the first columns C1 and the third columns C3 may overlap, and the second columns C2 and the fourth columns C4 may also overlap. The widths of the second columns C2 and the fourth columns C4 may be different from each other. That is, the pitch in the y direction of the first columns C1 and the pitch in the y direction of the third columns C3 may be different from each other, and a region in which the first columns C1 and the third columns C3 do not overlap may exist.

The number of first loop portions L1 and the number of third loop portions L3 may be different from each other. Furthermore, the number of second loop portions L2 and the number of fourth loop portions L4 may be different from each other. Even in these cases, as long as at least one of the above-described overlapping loop portions OL of n-type is formed, a leakage path through the p-type layer will not be formed between the upper electrode 24 and the outer peripheral end 10e of the semiconductor substrate 10.

### Third Embodiment

structure of Semiconductor Device 301

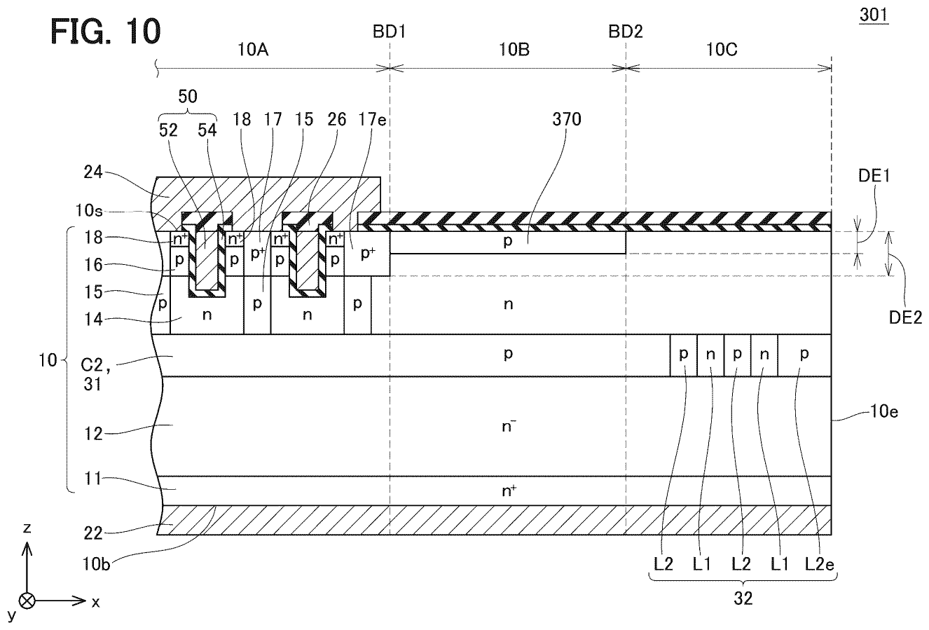

FIG. 10 shows a semiconductor device 301 according to a third embodiment. FIG. 10 is a drawing at a position similar to that of FIG. 2 of the first embodiment. The semiconductor device 301 of the third embodiment differs from the semiconductor device 1 of the first embodiment in its outer peripheral high breakdown-voltage structure. For portions common to both the first and third embodiments, the same reference numerals are used and detailed explanation is omitted.

In the first outer peripheral region 10B, an outer peripheral high breakdown-voltage structure 370 is disposed. The outer peripheral high breakdown-voltage structure 370 is a p-type diffusion region. The outer peripheral high breakdown-voltage structure 370 is disposed at a position exposed on the upper surface 10s of the semiconductor substrate 10. The outer peripheral high breakdown-voltage structure 370 is connected to a contact region 17e, which is disposed at a boundary between the active region 10A and the first outer peripheral region 10B. The outer peripheral high breakdown-voltage structure 370 extends from the contact region 17e toward the outer peripheral side. The outer peripheral high breakdown-voltage structure 370 is arranged so as to surround the periphery of the active region 10A when viewed from the direction perpendicular to the upper surface 10s. The depth of the outer peripheral high breakdown-voltage structure 370 from the upper surface 10s is depth DE1. The depth of the contact region 17e from the upper surface 10s is depth DE2. The depth DE1 is smaller than the depth DE2. In a modified example, the depth DE1 may be greater than or equal to the depth DE2.

The outer peripheral high breakdown-voltage structure 370 is a diffusion region formed by introducing p-type impurities into the upper drift region 14 using ion implantation technology. The concentration of p-type impurities in the outer peripheral high breakdown-voltage structure 370 is lower than the concentration of p-type impurities in the contact region 17e. Furthermore, the value obtained by integrating the p-type impurity concentration in the outer peripheral high breakdown-voltage structure 370 from the upper surface 10s in the depth direction is smaller than the value obtained by integrating the p-type impurity concentration in the contact region 17e from the upper surface 10s in the depth direction. That is, the amount of charge in the outer peripheral high breakdown-voltage structure 370 is smaller than the amount of charge in the contact region 17e.

The outer peripheral high breakdown-voltage structure 370, which is a low-concentration p-type layer, is referred to as a reduced surface field (RESURF) layer or a junction termination extension (JTE) layer. By forming the outer peripheral high breakdown-voltage structure 370 adjacent to the end of the contact region 17e, which is a high-concentration p-type layer, the depletion layer extends into both the upper drift region 14 (low-concentration n-type layer) and the outer peripheral high breakdown-voltage structure 370 (low-concentration p-type layer). As a result, the electric field at the end of the high-concentration p-type layer can be alleviated, making it possible to increase the breakdown voltage of the semiconductor device 301.

Although the embodiments have been described in detail above, these are merely examples and do not limit the scope of the present disclosure. The technology described in the claims includes various modifications and variations of the specific examples illustrated above. The technical elements described in the present specification or the drawings exhibit technical usefulness alone or in various combinations, and are not limited to the combinations described in the claims at the time of filing. Furthermore, the technology exemplified in the present specification or drawings is capable of achieving multiple objectives simultaneously, and the attainment of any one of these objectives alone is sufficient to provide technical utility.

### Modifications

In the present disclosure, the gate structure used in the active region 10A is not limited to a trench gate, and various gate structures such as a planar gate may be employed. Furthermore, the device structure disposed in the active region 10A is not limited to a MISFET. The device structure may be an insulated gate bipolar transistor (IGBT) or various types of diodes (for example, Schottky barrier diode, PN diode), or a structure combining these elements.

In the present embodiment, the numbers of the first loop portions L1 to the fourth loop portions L4, as well as the numbers of the ring portions 72_1 to 72_3, are merely examples, and these numbers are not particularly limited.

In the present specification, the case where the first conductivity type is n-type and the second conductivity type is p-type has been described, but the reverse configuration may also be adopted. That is, in the semiconductor device 1 shown in FIG. 1, a structure in which n-type and p-type are interchanged may also be adopted.

The shapes of the first SJ layer 31 and the third SJ layer 33 described in the present specification are not limited to stripe shapes, and various shapes may be employed. For example, when viewed from the direction perpendicular to the upper surface 10s, the plurality of n-type columns and the plurality of p-type columns may be arranged in a lattice pattern.

What is claimed is:

1. A semiconductor device comprising:
a semiconductor substrate having an upper surface and a lower surface;
an upper electrode disposed above the upper surface of the semiconductor substrate; and
a lower electrode disposed on the lower surface of the semiconductor substrate, wherein the semiconductor substrate has:
an active region in which a device structure capable of controlling current that flows between the upper electrode and the lower electrode is disposed;
a first outer peripheral region surrounding the active region, the first outer peripheral region having an outer peripheral high breakdown-voltage structure disposed in a vicinity of the upper surface of the semiconductor substrate; and
a second outer peripheral region surrounding the first outer peripheral region, the second outer peripheral region positioned in a range from an outer periphery of the first outer peripheral region to an outer peripheral end of the semiconductor substrate,
the semiconductor substrate includes:
a first superjunction layer disposed across the active region and the first outer peripheral region, and positioned below the outer peripheral high breakdown-voltage structure; and
a second superjunction layer disposed within the second outer peripheral region and surrounding the first superjunction layer,
the first superjunction layer includes a plurality of first columns of a first conductivity type and a plurality of second columns of a second conductivity type, the plurality of first columns and the plurality of second columns extend in a first direction and are alternately arranged along a second direction orthogonal to the first direction, and
the second superjunction layer includes at least one first loop portion of the first conductivity type and at least one second loop portion of the second conductivity type, each of the at least one first loop portion and the at least one second loop portion has an annular shape and surrounds the first superjunction layer, and the at least one first loop portion and the at least one second loop portion are alternately arranged from a position within the second outer peripheral region close to the first outer peripheral region toward the outer peripheral end of the semiconductor substrate.

2. The semiconductor device according to claim 1, wherein
the plurality of second columns of the first superjunction layer have second column end portions that are end portions in the first direction,
the second column end portions are positioned within the second outer peripheral region, and
the second column end portions are in contact with the at least one second loop portion.

3. The semiconductor device according to claim 2, wherein
the plurality of first columns of the first superjunction layer have first column end portions that are end portions in the first direction,
the first column end portions are positioned within the second outer peripheral region, and
the first column end portions are in contact with the at least one second loop portion and not in contact with the at least one first loop portion.

4. The semiconductor device according to claim 1, wherein
the at least one second loop portion includes a plurality of second loop portions,
among the plurality of second loop portions, an outermost second loop portion includes the outer peripheral end of the semiconductor substrate, and
the at least one first loop portion is in contact with an entire inner periphery of the outermost second loop portion.

5. The semiconductor device according to claim 1, wherein
a width in a short direction of each of the plurality of first columns and a width in a short direction of the at least one first loop portion are all equal to each other.

6. The semiconductor device according to claim 1, wherein
the semiconductor substrate further includes:
a third superjunction layer disposed across the active region and the first outer peripheral region, and positioned below the first superjunction layer; and
a fourth superjunction layer disposed within the second outer peripheral region, positioned below the second superjunction layer, and surrounding the third superjunction layer,
the third superjunction layer includes a plurality of third columns of the first conductivity type and a plurality of fourth columns of the second conductivity type, and the plurality of third columns and the plurality of fourth columns extend in a third direction and are alternately arranged along a fourth direction orthogonal to the third direction, and
the fourth superjunction layer includes at least one third loop portion of the first conductivity type and at least one fourth loop portion of the second conductivity type, each of the at least one third loop portion and the at least one fourth loop portion has an annular shape and surrounds the third superjunction layer, and the at least one third loop portion and the at least one fourth loop portion are alternately arranged from a position within the second outer peripheral region close to the first outer peripheral region toward the outer peripheral end of the semiconductor substrate.

7. The semiconductor device according to claim 6, wherein
the semiconductor substrate has an overlapping loop portion in which at least a part of the at least one first loop portion and at least a part of the at least one third loop portion overlap with each other when viewed from a direction perpendicular to the upper surface of the semiconductor substrate, and
the overlapping loop portion surrounds an entire outer periphery of the first outer peripheral region.

8. The semiconductor device according to claim 6, wherein
the plurality of fourth columns of the third superjunction layer have fourth column end portions that are end portions in the third direction,
the fourth column end portions are positioned within the second outer peripheral region, and
the fourth column end portions are in contact with the at least one fourth loop portion.

9. The semiconductor device according to claim 8, wherein
the plurality of third columns of the third superjunction layer have third column end portions that are end portions in the third direction,
the third column end portions are positioned within the second outer peripheral region, and
the third column end portions are in contact with the at least one fourth loop portion and not in contact with the at least one third loop portion.

10. The semiconductor device according to claim 6, wherein
the at least one fourth loop portion includes a plurality of fourth loop portions,
among the plurality of fourth loop portions, an outermost fourth loop portion includes the outer peripheral end of the semiconductor substrate, and
the at least one third loop portion is in contact with an entire inner periphery of the outermost fourth loop portion.

11. The semiconductor device according to claim 6, wherein
a width in a short direction of each of the plurality of third columns and a width in a short direction of the at least one third loop portion are all equal to each other.

12. The semiconductor device according to claim 1, wherein
the outer peripheral high breakdown-voltage structure includes a plurality of ring portions of the second conductivity type, and
each of the plurality of ring portions has an annular shape and surrounds the active region.

13. The semiconductor device according to claim 12, wherein
an interval between the plurality of ring portions is greater on an inner peripheral side than on an outer peripheral side.

14. The semiconductor device according to claim 1, wherein
the semiconductor substrate further includes a contact region of the second conductivity type disposed at a boundary between the active region and the first outer peripheral region and exposed on the upper surface of the semiconductor substrate,
the outer peripheral high breakdown-voltage structure includes a diffusion region of the second conductivity type disposed at a position exposed on the upper surface of the semiconductor substrate,
the diffusion region is connected to the contact region and extends from the contact region toward the outer peripheral end of the semiconductor substrate, and
a value obtained by integrating an impurity concentration in the diffusion region from the upper surface in a depth direction is smaller than a value obtained by integrating an impurity concentration in the contact region from the upper surface in the depth direction.

15. The semiconductor device according to claim 1, wherein
the semiconductor substrate is a wide bandgap semiconductor having a bandgap larger than a bandgap of silicon.

16. The semiconductor device according to claim 1, wherein
the first conductivity type is n-type and the second conductivity type is p-type.
